(19) United States
(12) Patent Application Publication
(10) Pub. No.: US 2015/0062837 A1
(43) Pub. Date: Mar. 5, 2015

(54) Lead frame for a premold sensor housing

(71) Applicants: Nico GREINER, Reutlingen (DE); Ingo HENKEL, Taipei City (TW); Eckart SCHELLKES, Kirchentellinsfurt (DE)

(72) Inventors: Nico GREINER, Reutlingen (DE); Ingo HENKEL, Taipei City (TW); Eckart SCHELLKES, Kirchentellinsfurt (DE)

(73) Assignee: Robert Bosch GmbH, Stuttgart (DE)

(21) Appl. No.: 14/472,671

(22) Filed: Aug. 29, 2014

(30) Foreign Application Priority Data
Aug. 30, 2013 (DE) 10 2013 217 303.2

(51) Int. Cl. H01L 21/48; H01L 23/495

(52) U.S. Cl. CPC H01L 21/4842; H01L 23/49541
USPC 361/748; 174/250; 29/827

(57) ABSTRACT

A lead frame for a premold sensor housing, in which the lead frame includes at least one angled section having essentially no rounding in an area of contact with the premold sensor housing, the area of contact being provided as a positioning area for a sensor element.

### RELATED APPLICATION INFORMATION

The present application claims priority to and the benefit of German patent application no. 10 2013 217 303.2, which was filed in Germany on Aug. 30, 2013, the disclosure of which is incorporated herein by reference.

### FIELD OF THE INVENTION

The present invention relates to a lead frame for a premold sensor housing. The present invention further relates to a method for manufacturing a lead frame for a premold sensor housing.

### BACKGROUND INFORMATION

It is believed that pressure sensors may be frequently installed into housings which are specifically injection molded in advance, so-called premold packages. In this connection, a metallic lead frame is overmolded with plastic and the sensor component or the sensor element is installed subsequently. Both thermoplastics and thermosetting plastics are used as plastics in this case. When thermosetting plastics are injection molded, the low viscosity (liquid as water) often results in coatings of the lead frame, which may interfere, for example, with additional processes and functions, for example, a proper functionality of electrical contacts of the pressure sensors.

It is believed to be understood to subsequently remove the above-named thin coatings in a so-called “def lash process.” This process typically includes a combination of electrochemical processes in baths, mechanical cleaning processes (for example, with the aid of a water jet) and rinse processes. In the area of the die rollover of the lead frame, the deflash process may result in some disadvantageous effects based on damage of the epoxy material.

Also believed to be understood are lead frame stampings including interlocking structures for interlocking a molding compound against thermomechanical stress, in which the lead frame stampings are essentially completely overmolded.

### SUMMARY OF THE INVENTION

An object of the present invention is to provide an improved lead frame for a premold sensor housing.

The objective may be achieved using a lead frame for a sensor housing, which is characterized in that the lead frame includes at least one angled section having essentially no rounding in an area of contact with the premold sensor housing, the area of contact being provided as a positioning area for a sensor element.

The objective may be further achieved using a method for manufacturing a lead frame for a sensor housing, including the following tasks:
punching a preform of the lead frame into a flat metallic material; and
forming an angled section in an area of contact of the lead frame with the premold sensor housing, the area of contact being provided as a positioning area for a sensor element, the angled section having essentially no rounding.

Advantageously, with the aid of the lead frame according to the present invention, an essentially impervious support section of flush configuration of the premold sensor housing is provided for a sensor element to be inserted subsequently. The smooth surface structure makes it largely impervious to subsequent chemical processes of the deflash process, and it is thus able to absorb mechanical stresses in a subsequent operation very well.

Specific embodiments of the lead frame according to the present invention and of the method according to the present invention are the subject matter of subclaims.

One specific embodiment of the lead frame according to the present invention is characterized in that the angled section is essentially situated in the area of the die rollover of the lead frame. This makes it possible to essentially eliminate the harmful influences of the die rollover completely.

Another specific embodiment of the lead frame according to the present invention is characterized in that the angled section has an angle in relation to the area of contact which is between approximately 30 degrees and approximately 135 degrees, the angle may be approximately 90 degrees. Advantageously, various angles are implemented in this manner which may be provided with the aid of different technical methods, an angle of approximately 90 degrees being very readily implementable in terms of manufacturing.

One specific embodiment of the method according to the present invention provides that the angled section is produced by a stamping process. In this way, a readily controllable manufacturing process step is used for forming the lead frame according to the present invention.

Another specific embodiment of the method according to the present invention provides that an angle is formed in the angled section in relation to the area of contact, which is between approximately 30 degrees and approximately 135 degrees, the angle may be approximately 90 degrees. Advantageously, a wide angle area is provided in this way, the most suitable angle being produced depending on the requirement.

The present invention is described in detail below to include additional features and advantages based on multiple drawings. All described or depicted features constitute the object of the present invention alone or in any arbitrary combination, irrespective of their summary in the patent claims or their back-reference as well as irrespective of their wording or depiction in the description or in the drawings. The drawings are primarily intended to illustrate the principles essential to the present invention and are not necessarily true to scale.

### BRIEF DESCRIPTION OF THE DRAWINGS

FIG. 1 shows a schematic top view of a premold sensor housing including an integrated lead frame.

FIG. 2 shows a cross-sectional view through a sub-area of a premold sensor housing including a conventional lead frame.

FIG. 3 shows a cross-sectional view through a sub-area of a premold sensor housing including a specific embodiment of a lead frame according to the present invention.

FIG. 4 shows a schematic sequence of one specific embodiment of the method according to the present invention.

### DETAILED DESCRIPTION

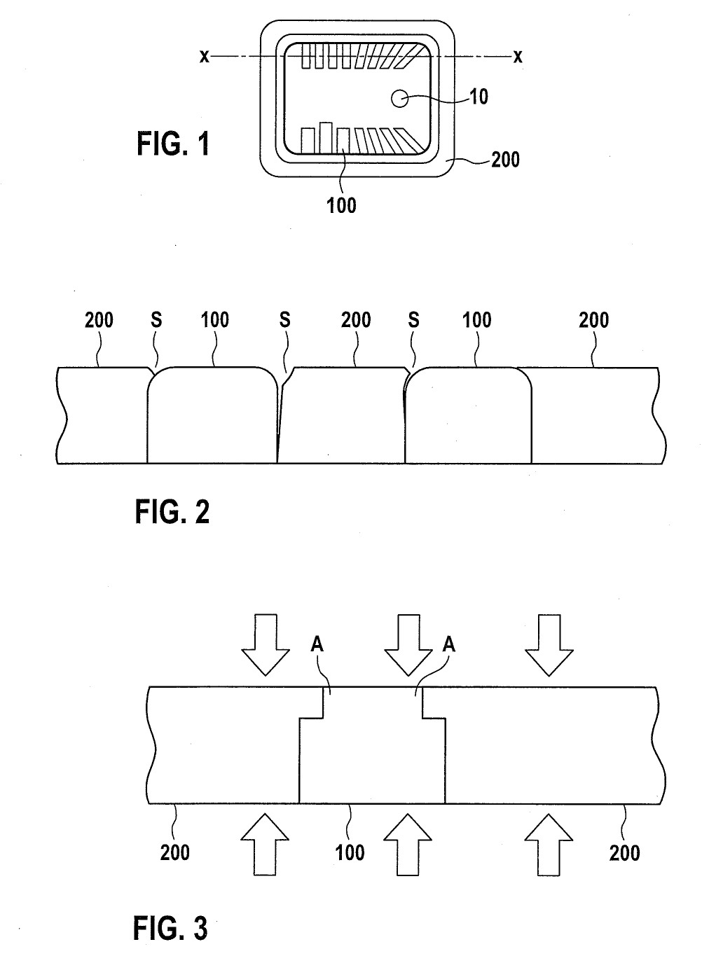

FIG. 1 shows a top view of a conventional lead frame 100 of metal (for example, essentially of copper, aluminum, steel, etc.) for an injection molded premold sensor housing 200, lead frame 100 being used in a subsequent process step for producing electrically conductive connections (not shown) to a sensor element (not shown). An opening 10 in premold sensor housing 200 is provided in order to provide a fluid connection to the sensor element for a medium. The sensor element may be used for applications in which a pressure change of the medium is to be detected, the overall structure of premold sensor housing 200, lead frame 100 and the sensor element may be formed as a pressure sensor, for example, for the automotive sector.

FIG. 2 shows a cross-sectional view through a conventional premold sensor housing 200 along an axis x-x from FIG. 1. It is apparent that lead frame 100 has a so-called die rollover due to a production-related punch process, which consists of roundings on the top edge of lead frame 100. The very thin structure made from molding compound (not shown) injected due to the die rollover may be removed very easily during the above-named deflash process or flakes off very easily. This is indicated in FIG. 2 as damages S to premold sensor housing 200. Damages S are caused due to the deflash process having a separating effect on a coating of plastic and lead frame 100, which is in fact desirable for the coatings; however, it may result in crack formation and material fractures on structures located in the immediate vicinity.

This may disadvantageously destroy a primary function of the sensor housing, such as tightness and freedom from caverns. This negative influence of the deflash process increases in direct proportion to the fineness of the structures in premold sensor housing 200, which pushes the known housing configurations to the limits of their usability in view of the increasing miniaturization and simultaneous increase in the requirement for quality regarding the robustness of pressure sensors, (for example, in relation to resistance to pressure change and maximum pressure).

FIG. 3 shows a cross-sectional view of one specific embodiment of lead frame 100 for a premold sensor housing 200 according to the present invention. It is apparent that two angled sections A having essentially perpendicular edges are formed on a surface of lead frame 100 in the area of a support for the sensor element. Angled sections A are formed as defined angles essentially without roundings. The above-named perpendicular edges may be formed with the aid of a stamping step, which is carried out, for example, with the aid of a separate stamping die or with the aid of a combination tool for punching and stamping. It is also advantageously possible for above-named angled section A to include angles in a range between approximately 30 degrees and approximately 135 degrees in relation to the surface or the area of contact for the sensor element, right angles being advantageously the simplest to implement in terms of manufacturing.

As a result, a “meander-shaped structuring” of lead frame 100 is formed from the top to the bottom, thus essentially preventing chemicals from being introduced during the deflash process. A basic effect of the above-named deflash process is indicated with the aid of three arrows which act on premold sensor housing 200 and lead frame 100 from the top and the bottom. According to the present invention, an impervious, flush surface structure is created, which essentially does not change during a subsequent operating load of the sensor by pressure change processes. As a result, improved interlocking of the mold material thus creates a mechanical support against the pressure loads during the deflash process.

The above-named stamping step essentially completely removes the die rollover from the lead frame manufacture, which disadvantageously produces thin and consequently easily damaged plastic structures. Essential for the specific configuration according to the present invention of lead frame 100 is the depth of the stamping, which is carried out in such a way that lead frame 100 is cut and not only deformed. In this way, a sharply structured top edge of lead frame 100 is created, which causes an improved blocking against the penetration of plastic material of premold sensor housing 200.

This also results in an enlargement of a joining surface of the plastic on the side of lead frame 100. Finally, the above-named meander-shaped structure counteracts leaks, which prevents a chemical impact on joining surfaces lying deeper in the mold, and in this manner advantageously increases the strength of the connection of the mold to the lead frame in the deflash process and in the sensor application. This essentially eliminates consequential errors originating from a failure of the above-named connection.

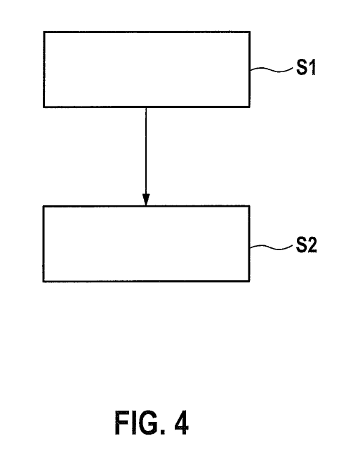

FIG. 4 shows a schematic sequence of one specific embodiment of the method according to the present invention.

In a first step S1, a preform of lead frame 100 is punched into a flat metallic material.

In a step S2, an angled section A is formed in an area of contact of lead frame 100 including premold sensor housing 200, which is provided as a positioning area for a sensor element, angled section A having essentially no rounding.

In summary, the present invention provides a configuration of a lead frame, which in contrast to known concepts means that space is saved in the premold sensor housing. As a result, a deliberately thicker coating with molding compound is made possible, since no tolerances need to be considered in the overmolding process. Advantageously, this results in extending the life of molding tools, since the geometry of the used molds may be configured more simply. The technique according to the present invention makes it possible to manufacture sensor housings which are robust to pressure changes, which allows the known processes for removing coatings without damaging the housing.

In contrast to known lead frame stampings or lead frames for interlocking a molding compound against thermomechanical stress, the lead frame structure according to the present invention brings an improvement of the deflash resistance, in particular with regard to the impact of chemistry and electrochemistry.

Although the present invention was depicted based on an exemplary embodiment for a premold sensor housing including a pressure sensor element, it is of course possible that the present invention is also usable for other sensor applications involving pressure changes having at least one free access to a fluid or a medium, in which it is important to eliminate harmful effects of a die rollover.

Those skilled in the art will thus combine or modify the disclosed features of the present invention in a suitable way, without departing from the essence of the present invention.

What is claimed is:

1. A lead frame for a premold sensor housing, comprising:
at least one angled section having essentially no rounding in an area of contact with the premold sensor housing, the area of contact being provided as a positioning area for a sensor element.

2. The lead frame of claim 1, wherein the angled section is essentially situated in the area of a die rollover of the lead frame.

3. The lead frame of claim 1, wherein the angled section has an angle in relation to the area of contact, which is between approximately 30 degrees and approximately 135 degrees.

4. A method for manufacturing a lead frame for a premold sensor housing, the method comprising:
punching a preform of the lead frame into a flat metallic material; and
forming an angled section in an area of contact of the lead frame with the premold sensor housing, the area of contact being provided as a positioning area for a sensor element, the angled section having essentially no rounding.

5. The method of claim 4, wherein the angled section is produced by a stamping process.

6. The method of claim 4, wherein an angle is formed in the angled section in relation to the area of contact, which is between approximately 30 degrees and approximately 135 degrees.

7. The method of claim 4, wherein an angle is formed in the angled section in relation to the area of contact, the angle being approximately 90 degrees.

8. A sensor, comprising:
a premold housing, wherein pressure changes are provided on the premold housing including a lead frame;
wherein the lead frame for the premold sensor housing, includes at least one angled section having essentially no rounding in an area of contact with the premold sensor housing, the area of contact being provided as a positioning area for a sensor element.

9. The lead frame of claim 1, wherein the angled section has an angle in relation to the area of contact, the angle being approximately 90 degrees.
